(19) United States
(12) Patent Application Publication
(10) Pub. No.: US 2008/0248644 A1
(43) Pub. Date: Oct. 9, 2008

(54) METHOD OF FABRICATING A SEMICONDUCTOR DEVICE WITH A POROUS DIELECTRIC FILM

(75) Inventor: Guo lin Liu, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI ELECTRIC INDUSTRY CO., LTD., Tokyo (JP)

(21) Appl. No.: 12/046,522

(22) Filed: Mar. 12, 2008

(30) Foreign Application Priority Data
Apr. 6, 2007 (JP) 2007100551

(51) Int. Cl. H01L 21/31; H01L 21/768

(52) U.S. Cl. 438/653; 438/787; 257/E21.24; 257/E21.584

(57) ABSTRACT

In the fabrication of a semiconductor device, an SiO₂GeO₂ film is formed on a substrate, then washed with water to dissolve the GeO₂, leaving a porous SiO₂ film. The SiO₂GeO₂ film may be deposited directly on the substrate, or an SiGe film may be deposited on the substrate and then oxidized to form the SiO₂GeO₂ film. The porous SiO₂ film has an easily controllable dielectric constant and can be advantageously used as an interlayer dielectric film.

### BACKGROUND OF THE INVENTION

1. Field of the Invention

The present invention relates to a method of fabricating a semiconductor device including a porous silicon oxide interlayer dielectric film.

2. Description of the Related Art

As the dimensions of the features in semiconductor devices continue to shrink, the spaces between wires in their interconnection layers also tend to shrink. In a device with very small wiring spacing, considerable parasitic capacitance can be present between adjacent wires, producing what is termed ‘interconnect delay’ by delaying signal propagation on the wires. Interconnect delay becomes particularly noticeable beyond the ninety-nanometer technology node in the International Technology Roadmap for Semiconductors (ITRS). This node is a technology level at which the half pitch of interconnections in a dynamic random-access memory (DRAM) is ninety nanometers (90 nm).

A known method of reducing interconnect delay is to use a material with a low dielectric constant (a so-called low-k material) for the interlayer dielectric films in which interconnecting wires are embedded. For wiring spacing dimensions smaller than 90 nm, a dielectric constant of about 3.0 is necessary.

Porous materials are known to make effective low-k dielectric films. The dielectric constant of a porous film decreases with increasing pore diameter and increasing porosity, porosity being the fraction of the film volume occupied by the pores. That is, the dielectric constant decreases with decreasing density of the film.

Japanese Patent Application Publication (JP) 9-64323 discloses a method of forming a porous film on a silicon substrate by anodizing the substrate in a 1:1 solution of hydrogen fluoride (HF) and ethanol (C₂H₅OH).

JP 10-256363 discloses a method of using a foaming agent such as triphenylsilane to generate air bubbles in a silicon resin, which is then cured so that the bubbles become pores.

JP 11-186258 discloses a method in which a silicon oxide film with excess silicon is formed, and the excess silicon is removed to leave pores.

These methods are capable of producing films with dielectric constants lower than 3.0, but in all three methods it is difficult to control the pore size and porosity, so it is difficult to obtain a desired dielectric constant consistently. Overcoming the difficulties in these methods would require a complex fabrication process with many steps.

There is accordingly a need for a method of consistently forming a porous film with a desired dielectric constant in a small number of steps.

### SUMMARY OF THE INVENTION

An object of the present invention is to fabricate a semiconductor device including a porous interlayer dielectric film with an easily controllable dielectric constant.

A further object is to form the porous interlayer dielectric film in a small number of steps.

A method of fabricating a semiconductor device according to the present invention includes the steps of forming a silicon-dioxide-germanium-dioxide (SiO₂GeO₂) film on a substrate and washing the SiO₂GeO₂ film in water, thereby dissolving the germanium dioxide (GeO₂) included in the film and leaving a porous silicon dioxide (SiO₂) film.

The SiO₂GeO₂ film may be deposited directly on the substrate, or a silicon-germanium (SiGe) film may be deposited on the substrate and then oxidized to form the SiO₂GeO₂ film.

The dielectric constant of the porous SiO₂ film can be easily controlled by controlling the ratio of SiO₂ to GeO₂ in the SiO₂GeO₂ film.

The porous SiO₂ film can be advantageously used as an interlayer dielectric film. For example, interconnecting wires may be formed in trenches in the porous SiO₂ film.

### BRIEF DESCRIPTION OF THE DRAWINGS

In the attached drawings:

FIGS. 1, 2, and 3 illustrate steps in the fabrication of a semiconductor device according to a first embodiment of the invention;

FIGS. 4 and 5 illustrate steps in the fabrication of a semiconductor device according to a second embodiment of the invention; and

FIGS. 6, 7, 8, and 9 illustrate further exemplary steps in the fabrication of a semiconductor device according to the first and second embodiments.

### DETAILED DESCRIPTION OF THE INVENTION

Embodiments of the invention will now be described with reference to the attached drawings, in which like elements are indicated by like reference characters.

### First Embodiment

In the first embodiment, an SiGe film is deposited on a substrate and oxidized to form an SiO₂GeO₂ film, which is then washed to dissolve the GeO₂ and leave a porous SiO₂ film.

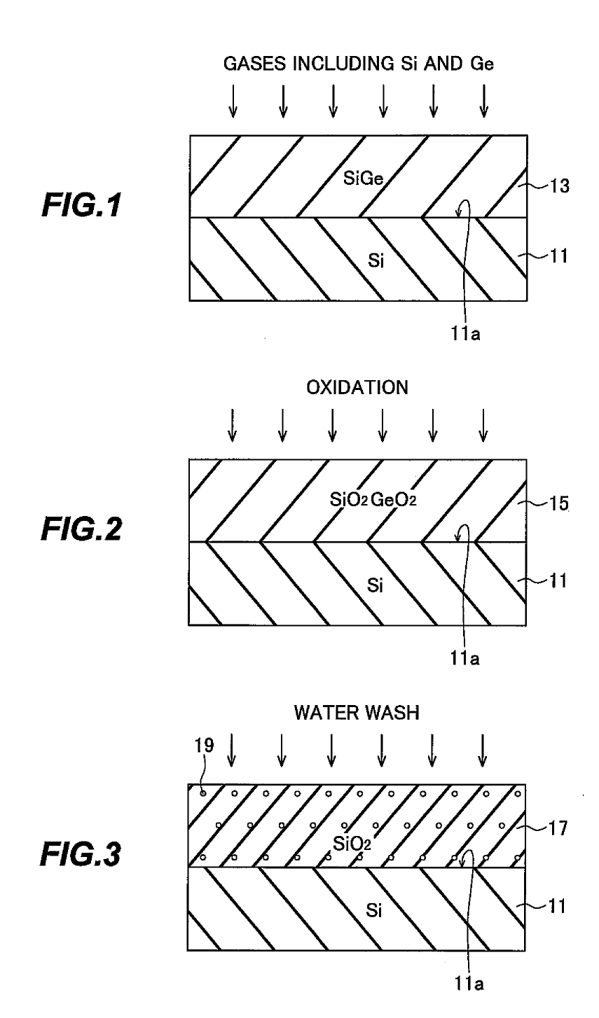

Referring to FIG. 1, the SiGe film 13 is deposited on the upper surface 11a of a substrate 11 such as a silicon (Si) substrate, a silicon-on-insulator (SOI) substrate, or any suitable other type of semiconductor substrate. A silicon substrate is illustrated in FIG. 1. The substrate may include microelectronic circuitry that has been formed by well-known methods. The upper surface 11a of the substrate 11 may be covered by a buffer film such as a silicon nitride (SiN) film.

The SiGe film 13 is deposited by conventional chemical vapor deposition (CVD). The CVD source gas is a mixture of a gas containing silicon (Si) and a gas containing germanium (Ge): for example, a mixture of silane (SiH₄) and germane (GeH₄), or a mixture of silane (SiH₄) and germanium tetrafluoride (GeF₄). The silicon in the silicon-containing gas forms chemical bonds with the germanium in the germanium-containing gas to create a crystalline SiGe film 13. The thickness of the SiGe film 13 is preferably in the range from about 75 nm to about 400 nm.

Since a porous film will be created by oxidizing the SiGe film 13 to form an SiO₂GeO₂ film and then dissolving the GeO₂ to leave an SiO₂ film with pores, and since the ratio of SiO₂ to GeO₂ in the SiO₂GeO₂ film is equal to the ratio of silicon to germanium in the SiGe film 13, the ratio of silicon to germanium in the SiGe film 13 determines the porosity of the final SiO₂ film. The pore size also depends on the ratio of silicon to germanium in the SiGe film 13. As the pore size and porosity determine the dielectric constant of the final SiO₂ film, the dielectric constant can be controlled by controlling the ratio of silicon to germanium in the SiGe film 13. A statistical relation between the composition ratio and the dielectric constant can be determined experimentally beforehand and used for control purposes. For a dielectric constant of about 3.0, it has been found that the SiGe film 13 should include approximately equal amounts of silicon and germanium. Such a film can be obtained by use of a CVD source gas in which the silicon-containing gas and the germanium-containing gas are mixed in a ratio of about 1:1.

The oxidation of the SiGe film 13 to form an SiO₂GeO₂ film 15 is illustrated in FIG. 2. Available methods of oxidation include wet oxidation, vapor-phase sulfuric-acid oxidation, radical (plasma) oxidation, and other known techniques. For example, a 400-nm SiGe film 13 may be oxidized by wet oxidation in a furnace as follows.

First, the substrate 11 on which the SiGe film 13 has been formed is placed in the furnace in a nitrogen atmosphere at standard pressure, and the temperature of the furnace is raised to 850° C. over a period of about twenty minutes. An atmosphere consisting of a mixture of gaseous hydrogen (H₂), oxygen (O₂), and nitrogen (N₂) is then introduced into the furnace and the SiGe film 13 is oxidized in this atmosphere at 850° C. for, preferably, about sixty minutes. The ratio of the gas flows in the furnace is preferably one part hydrogen to one part oxygen to four parts nitrogen (H₂:O₂:N₂=1:1:4). Next, an oxygen atmosphere is introduced into the furnace and the SiGe film 13 is exposed to this atmosphere, preferably for about five minutes. Finally, a nitrogen atmosphere is introduced into the furnace and the temperature is reduced to approximately standard temperature over a period of about five minutes.

In FIG. 3, the SiO₂GeO₂ film 15 created by the oxidation step is converted to a porous SiO₂ film 17 by washing in water, or in an aqueous solution of hydrogen peroxide. The water or aqueous hydrogen peroxide solution should be free of impurities. If water is used, for example, it is preferable to use distilled water.

In the crystalline SiO₂GeO₂ film 15, the GeO₂ is soluble in the water or aqueous hydrogen peroxide, while the SiO₂ is insoluble in the water or aqueous hydrogen peroxide. Washing in water or aqueous hydrogen peroxide accordingly dissolves the GeO₂ and leaves the SiO₂, the spaces vacated by the GeO₂ becoming pores 19. The washing process can be carried out simply by immersing the substrate 11 with its SiO₂GeO₂ film 15 in water or aqueous hydrogen peroxide. Immersion in water or aqueous hydrogen peroxide at a temperature of 20° C. for about sixty minutes, for example, will adequately dissolve the GeO₂ in an SiO₂GeO₂ film 15 up to about 500 nm thick.

The porous SiO₂ film 17 can then be used as an interlayer dielectric film to insulate microelectronic circuitry in the substrate 11 from interconnections formed on or in the porous SiO₂ film 17.

The formation and oxidation of the SiGe film 13 in the first embodiment can be carried out by well-known procedures involving only a small number of steps. The first embodiment accordingly provides a simple method of forming a porous dielectric film, in which it is only necessary to add a washing step to these well-known procedures. The dielectric constant of the porous film can be easily and accurately controlled by controlling the gas ratio when the SiGe film 13 is deposited. A porous SiO₂ film 17 with a desired dielectric constant can accordingly be formed easily, without significant impact on the cost or throughput of the semiconductor fabrication process.

### Second Embodiment

In the second embodiment, an SiO₂GeO₂ film is deposited directly on the substrate and then washed to dissolve the GeO₂ and leave a porous SiO₂ film.

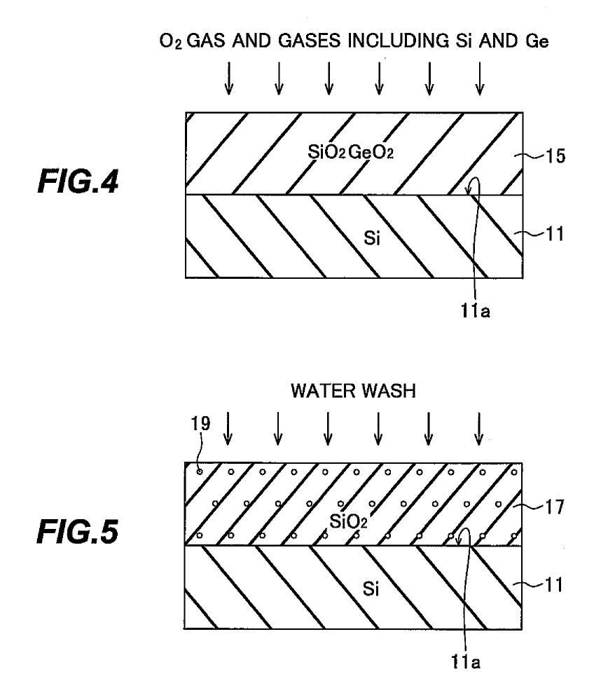

Referring to FIG. 4, the SiO₂GeO₂ film 15 is deposited on the upper surface 11a of the substrate 11. A silicon substrate 11 is illustrated in FIG. 4, but other types of semiconductor substrates may be used, as noted in the first embodiment.

The SiO₂GeO₂ film 15 is deposited by CVD. The CVD source gas is a mixture of a gas containing silicon, a gas containing germanium, and a molecular oxygen (O₂) gas: for example, a mixture of SiH₄, GeH₄, and O₂, or a mixture of SiH₄, GeF₄, and O₂. The silicon (Si) in the silicon-containing gas, the germanium (Ge) in the germanium-containing gas, and the oxygen (O₂) form chemical bonds to create an SiO₂GeO₂ film 15 with a crystalline structure.

As in the first embodiment, a porous film will be created by dissolving the GeO₂ to leave an SiO₂ film with pores, and the dielectric constant of the porous film can be controlled by controlling the ratio of SiO₂ to GeO₂ in the SiO₂GeO₂ film 15, which is accomplished by controlling the composition ratio of the CVD source gas. For a dielectric constant of about 3.0, SiO₂ and GeO₂ should be present in about equal proportions in the SiO₂GeO₂ film 15. This can be obtained by using a source gas in which the silicon-containing gas, the germanium-containing gas, and the oxygen gas are mixed in a ratio of about 1:1:4. The dielectric constant depends principally on the relative proportions of the silicon-containing gas and the germanium-containing gas.

In FIG. 5, the SiO₂GeO₂ film 15 deposited by CVD on the substrate 11 is converted to a porous SiO₂ film 17 by washing in water, or an aqueous solution of hydrogen peroxide. The washing procedure is the same as in the first embodiment, so a detailed description will be omitted.

Between the CVD step in FIG. 4 and the washing step in FIG. 5, the SiO₂GeO₂ film 15 may be annealed, preferably at a temperature of about 600° C. for about five minutes in an atmosphere of oxygen (O₂) and nitrogen (N₂) at standard pressure. The volumetric fraction of oxygen in the atmosphere is preferably at least 20%. The purpose of the annealing is to improve the quality of the SiO₂GeO₂ film 15 by supplying additional oxygen to eliminate oxygen voids, which may occur due to incomplete bonding of the silicon and germanium with the oxygen in the CVD source gas.

Compared with the first embodiment, the second embodiment offers higher throughput because the SiO₂GeO₂ film 15 is created in a single CVD step, instead of requiring a CVD step and an oxidation step.

In a variation of the first and second embodiments, after the porous SiO₂ film 17 has been formed as illustrated in FIG. 3 or FIG. 5, it is annealed, preferably at a temperature of from 600° C. to 1200° C. for about five minutes in an atmosphere of oxygen (O₂) and nitrogen (N₂) or oxygen (O₂) and argon (Ar) at standard pressure. The volumetric fraction of oxygen in the atmosphere is preferably at least 20%. The purpose of this annealing step is to improve the quality of the porous SiO₂ film 17 by supplying additional oxygen to eliminate oxygen voids that may still be present.

In another variation of the first and second embodiments, after the porous SiO₂ film 17 has been created as illustrated in FIG. 3 or FIG. 5, or after the porous SiO₂ film 17 has been annealed as described above, a wiring pattern is formed in the porous SiO₂ film 17. The wiring pattern may be formed by conventional methods. As an example, a copper damascene method will be described below.

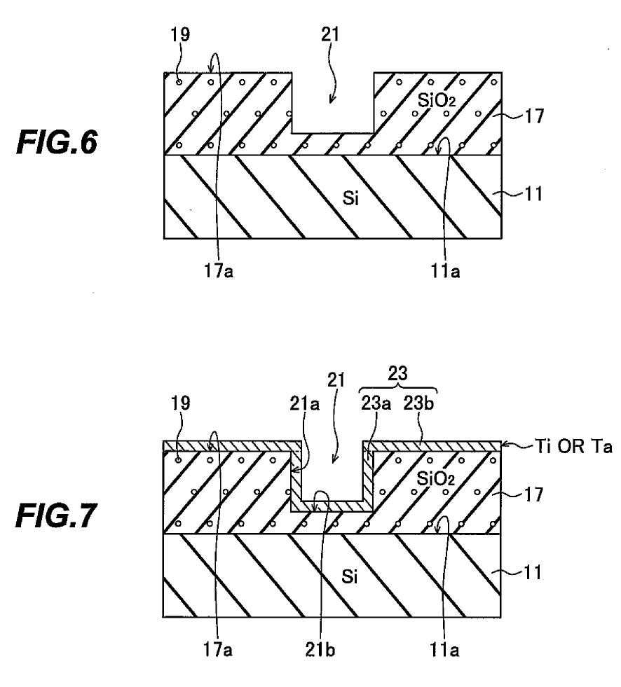

In this method, first a pattern of trenches is formed in the upper surface 17a of the porous SiO₂ film 17. FIG. 6 illustrates one trench 21, shown in cross-section. The trenches are formed by photolithography and dry etching, e.g., reactive ion etching (RIE).

Next, referring to FIG. 7, a barrier layer 23 is uniformly deposited, covering the upper surface 17a of the porous SiO₂ film 17 and the walls 21a and floors 21b of the trenches 21. The barrier layer 23 is a layer of an electrically conductive metal such as titanium (Ti) or tantalum (Ta), as indicated, and may be deposited by CVD, plasma vapor deposition (PVD), or other known methods. The purpose of the barrier layer 23 is to prevent diffusion of the copper interconnect material that will be deposited next, and to provide a surface with which the interconnect material will make tight contact. If the width of the interconnecting wires will be 300 nm, for example, the thickness of the barrier layer 23 should be in the range from 5 nm to 50 nm. The inner barrier layer 23a covering the walls 21a and floors 21b of the trenches 21 preferably has the same thickness as the outer barrier layer 23b disposed on the upper surface 17a of the porous SiO₂ film 17.

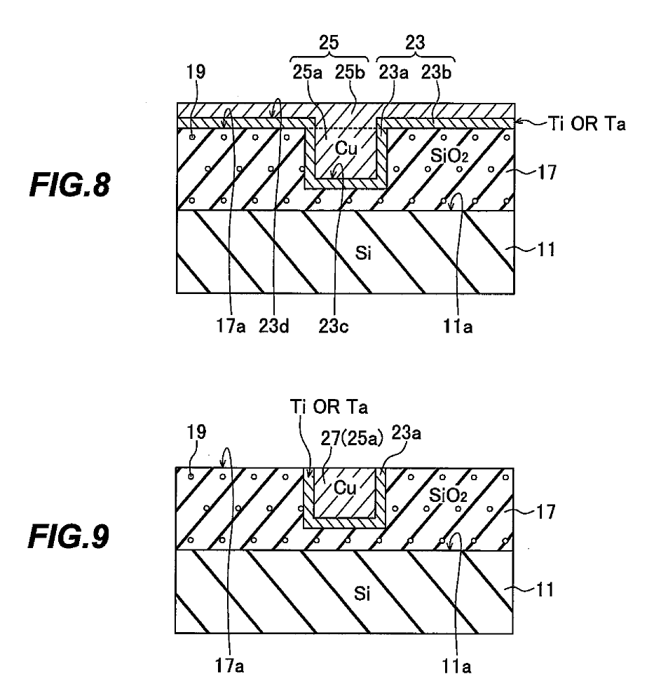

Next, referring to FIG. 8, a layer of an interconnect material, specifically copper (Cu), which is more electrically conductive than the barrier material (Ti or Ta), is deposited on the entire barrier layer 23, filling the trenches and covering both the inner barrier layer 23a and the outer barrier layer 23b. The result is a copper layer 25 comprising an inner copper layer 25a that fills the trenches up to the level of the upper surface 17a of the porous SiO₂ film 17, and an outer copper layer 25b disposed above the level of the upper surface 17a.

The copper layer 25 is preferably deposited by an electroplating process as follows. First a seed metal layer of copper is deposited by CVD on the barrier layer 23, covering both the inner barrier layer 23a and the outer barrier layer 23b with a thickness of at least one copper atomic layer. Next, the seed metal is used as a cathode to deposit additional copper from a copper electrolyte solution. The seed metal layer is deposited on the entire surface of the barrier layer 23 to allow an adequate flow of electroplating current. Consequently, additional copper is plated both onto the walls and floors 23c of the trenches and onto the barrier surface 23d outside the trenches. The electroplating process continues at least until the trenches are completely filled.

Next, referring to FIG. 9, the outer copper layer 25b and outer barrier layer 23b are entirely removed by, for example, a well-known chemical-mechanical polishing (CMP) process, exposing the upper surface 17a of the porous SiO₂ film 17 and leaving interconnecting wires 27 composed of the inner copper layer 25a, surrounded by the barrier layer 23a, in the trenches.

The metal materials used in the process above are exemplary. The barrier material is not limited to titanium or tantalum, and the interconnect material is not limited to copper.

In addition to the variations of the first and second embodiments described above, those skilled in the art will recognize that further variations are possible within the scope of the invention, which is defined in the appended claims.

What is claimed is:

1. A method of fabricating a semiconductor device, comprising:
forming an SiO₂GeO₂ film on a substrate; and
washing the SiO₂GeO₂ film in water, thereby dissolving the GeO₂ included in the SiO₂GeO₂ film and leaving a porous SiO₂ film.

2. The method of claim 1, wherein the SiO₂GeO₂ film is crystalline.

3. The method of claim 1, wherein washing the SiO₂GeO₂ film in water comprises washing the SiO₂GeO₂ film in an aqueous solution of hydrogen peroxide.

4. The method of claim 1, wherein SiO₂ and GeO₂ are present in substantially equal proportions in the SiO₂GeO₂ film.

5. The method of claim 1, wherein forming the SiO₂GeO₂ film further comprises:
depositing an SiGe film on the substrate from a mixture of a gas containing silicon and a gas containing germanium; and
oxidizing the SiGe film.

6. The method of claim 5, wherein the gas containing silicon is SiH₄.

7. The method of claim 5, wherein the gas containing germanium is GeH₄.

8. The method of claim 5, wherein the gas containing germanium is GeF₄.

9. The method of claim 1, wherein forming the SiO₂GeO₂ film comprises depositing an SiO₂GeO₂ film from a mixture of a gas containing silicon, a gas containing germanium, and a molecular oxygen gas.

10. The method of claim 9, wherein the gas containing silicon is SiH₄.

11. The method of claim 9, wherein the gas containing germanium is GeH₄.

12. The method of claim 9, wherein the gas containing germanium is GeF₄.

13. The method of claim 9, further comprising annealing the SiO₂GeO₂ film before washing the SiO₂GeO₂ film.

14. The method of claim 13, wherein annealing the SiO₂GeO₂ film further comprises heating the SiO₂GeO₂ film in an atmosphere including at least 20% oxygen.

15. The method of claim 1, further comprising forming an electrically conductive wire in the porous SiO₂ film.

16. The method of claim 15, wherein forming the electrically conductive wire further comprises:
forming a trench in a surface of the porous SiO₂ film;
depositing a barrier layer on the porous SiO₂ film, the barrier layer including an inner barrier layer covering wall and floor surfaces of the trench and an outer barrier layer covering the surface of the porous SiO₂ film outside the trench;
depositing a layer of interconnect material, the layer of interconnect material including an inner layer of interconnect material filling the trench up to a level even with the surface of the porous SiO₂ film outside the trench and an outer layer of interconnect material covering the inner layer of interconnect material and the surface of the porous SiO₂ film outside the trench; and
removing the outer layer of interconnect material and the outer barrier layer, leaving the inner layer of interconnect material to form the electrically conductive wire.

17. The method of claim 16, further comprising annealing the porous SiO₂ film before forming the electrically conductive wire.

18. The method of claim 17, wherein annealing the porous SiO₂ film further comprises heating the porous SiO₂ film in an atmosphere including at least 20% oxygen.
